(19) United States
(12) Patent Application Publication
(10) Pub. No.: US 2005/0189315 A1
(43) Pub. Date: Sep. 1, 2005

(54) Method for manufacturing gratings in semiconductor materials

(76) Inventors: D. Gordon Knight, London (CA); Michael Cleroux, Greely (CA); Richard Finlay, Toronto (CA)

Correspondence Address: LACKENBACH SIEGEL, LLP, LACKENBACH SIEGEL BUILDING, 1 CHASE ROAD, SCARSDALE, NY, 10583, US

(21) Appl. No.: 10/978,633

(22) Filed: Nov. 1, 2004

Related U.S. Application Data
(60) Provisional application No. 60/516,641, filed on Oct. 31, 2003.

(51) Int. Cl. H01L 21/00; H01S 3/08; C23F 1/00

(52) U.S. Cl. 216/2; 438/32

(57) ABSTRACT

The present invention is a combination of in-situ etching using a grating mask that is formed in semiconductor material only and the subsequent overgrowth of additional semiconductor material to enclose the grating structure prior to exposure to the atmosphere and the contaminants therein. The present invention is based on a two-stage process. First the grating pattern is defined in a semiconductor material, which is the grating mask. This grating mask is created at a position above the material that is to ultimately contain the grating pattern. Upon the completion of the fabrication of the grating mask, the semiconductor structure is moved to a reactor, where in the second stage, the grating pattern defined by the grating mask is transferred into the underlying semiconductor layers by in-situ etching. The grating is subsequently overgrown with additional semiconductor material while in the same reactor, thereby not exposing the etched grating pattern to the atmosphere thereby reducing the contaminants in the grating structure of the semiconductor laser.

This application incorporates by reference and claims priority from U.S. Provisional Patent Application, Ser. No. 60/516,641, Filed Oct. 31, 2003.

### FIELD OF INVENTION

The invention pertains to the field of semiconductor lasers and in particular to a method for manufacturing gratings in semiconductor materials.

### BACKGROUND

Semiconductor lasers have become increasingly popular as sources for optical communications, due to their low cost and high performance. In particular distributed feedback (DFB) lasers are important in dense wavelength division multiplexing applications where accurate and stable optical signals are required. DFB semiconductor lasers are comprised of n-type and p-type semiconductor material.

Typically, in DFB lasers, a grating pattern is etched either adjacent to the active region to form an index-coupled laser, or directly into the active region to form a gain-coupled laser. The gratings are then overgrown with additional semiconductor material. The quality of this grating is a key determinant of the laser's performance. All aspects of the grating, including especially the grating shape, depth, period, uniformity, and the cleanliness and crystalline properties of the grating interface region, determine the quality of the output signal from the laser. Many limits to the performance arise from conventional methods of etching, and conventional methods of growth on top of the grating interface. Conventional methods result in poor dimensional tolerances of the grating and residual contaminants. Another problem with conventional methods is that the grating is exposed to the atmosphere between the etching and the overgrowth stages, allowing contamination of the semiconductor structure.

With the conventional approach to the manufacture of these semiconductor structures, contaminants, especially silicon-containing material, accumulate at the grating regrowth interface. For example, this contamination layer is a n-type dopant in the InGaAs/InP material system. The contamination layer degrades the electrical performance of the device, especially when the contaminant is in p-type material. Designers are often forced to compensate for the n-type dopant by the addition of excessive p-type dopants, but excessive p-type dopants can increase the optical absorption of the waveguide. Furthermore, the amount of contamination has been correlated with the rate of device degradation, particularly for gain-coupled designs where the growth interface is in the active region. Because the contamination cannot be controlled, these influences on performance and reliability are especially problematic in a manufacturing setting.

Gratings are conventionally etched in a chemical solution (for example HBr:HNO₃:H₂O), or using reactive ion etching. The etch mask is typically a photoresist, or a dielectric material such as SiO₂, or SiNₓ. Other less conventional methods of etching gratings employ a semiconductor grating mask as the etch mask material. These methods include repetitive oxidation and oxide-stripping cycles, as described in U.S. Pat. No. 5,567,659, and direct wet chemical etching as described in U.S. Pat. No. 6,551,936. All these methods expose the final grating to water and ambient air, allowing contamination to collect on the etched surface.

An existing approach used to mitigate the impact of contamination by n-type dopants, is to put the grating on the n-side of the structure. However there are severe limitations to this approach. The contamination at the growth interface would still introduce an uncontrollable amount of n-type doping, impacting control of the electrical properties of the device. Furthermore, in applications with a gain-coupled grating, where the grating is etched into the active region, this approach would require the active region to be n-type. Restricting laser design to n-type active regions is not desirable because most current laser designs employ undoped or p-type active regions. Putting the grating on the n-side of the structure is more suitable for index-coupled gratings, but even then there are limitations to this approach. To make an index-coupled grating in n-type material, the grating would be underneath the active region. In this approach, the grating is etched before the active region is grown, and so there is no opportunity to adjust the grating due to random variations in the growth of the active region. For example, it would not be possible to adjust the period of the grating for each wafer according to the measured properties of the active region on that wafer thereby eliminating an important aspect of control of the manufacturing process. Putting the grating on the n-side of the structure to mitigate the impact of silicon contamination is a limiting solution, whether for index-coupled or gain-coupled gratings.

Another problem with conventional approaches to manufacturing gratings, especially gain-coupled gratings, is the challenge of achieving good control of the grating shape and depth across the wafer. Wet chemical etching, which is typically used in manufacturing, contributes to variations in grating depth and shape across the wafer. One of the causes of the variation in depth and shape is spatial variation in surface wetting. Another cause is spatial variation in the diffusion or other transport of reactants and etch products to and from the etch surface. Other etch processes use a plasma or neutral reactive radicals. These etch processes also contribute to variations in grating depth. One of the causes of depth variation in these etch processes is spatial variation in the density of the plasma or the density of the reactive radicals. The challenges are especially great when etching a gain-coupled grating because active regions in modern semiconductor lasers are typically comprised of quantum-wells and quantum-barriers stacked in layers, surrounded by material of other compositions, and the etch properties are different in each component of the active region.

An existing approach to reduce contamination at a growth interface, while achieving good control of etch depth and shape, is in-situ etching. In-situ etching is etching inside a reactor that is conventionally used for epitaxial growth, such as a reactor for molecular beam epitaxy, chemical vapor deposition, or metal organic chemical vapor deposition (MOCVD). After etching, the same reactor can be used to grow a semiconductor material on top of the etched surface. For example, Knight in U.S. Pat. No. 5,869,398 has shown that InP may be etched in an MOCVD reactor and then additional Inp may be grown on the etched surface without exposing the surface to atmosphere. This in-situ etch and overgrowth procedure reduced the levels of silicon and oxygen contamination at the growth interface compared to samples that did not receive in-situ etching prior to overgrowth. A limitation of this approach is that conventional methods of defining the pattern to be etched are not suitable. With conventional methods of defining the pattern to be etched, the sample must be removed from the reactor to remove the mask material. For example, if a pattern was defined in photoresist or dielectric (such as SiO₂ or SiNₓ), the wafer would have to be removed from the reactor in order to strip this masking material, thereby exposing the etched surface to contamination.

Considerable effort has been expended in the attempt to improve the overall process for manufacturing gratings in semiconductor lasers. Pakulski et al. in U.S. Pat. No. 5,567,659 demonstrated a process based on repeated cycles of oxidation and stripping of the oxide that gives good control of grating depth. Pakulski et al. in U.S. Pat. No. 6,551,936 have demonstrated another technique for the generation of patterns on a semiconductor structure suitable for application to a grating in a DFB laser. In both of these techniques the grating is exposed to the atmosphere prior to overgrowth. Whilst progress has been made in individual manufacturing areas, no overall method has been shown to meet the requirements of limiting or eliminating contamination of the etched grating surface and achieving good depth control during manufacturing.

Therefore there is a need for a new manufacturing process enabling the fabrication of gratings in semiconductor material.

This background information is provided for the purpose of making known information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a method for manufacturing gratings in semiconductor materials. In accordance with one aspect of the present invention there is provided a method for manufacturing a grating pattern in one or more layers of semiconductor material, the method comprising the steps of: forming a grating pattern in a semiconductor material grown on top of the one or more layers, thereby forming a semiconductor grating mask; transferring the grating pattern into the one or more layers using in-situ etching in an epitaxial growth reactor; and overgrowing semiconductor material on the one or more layers prior to removal from the epitaxial growth reactor.

### BRIEF DESCRIPTION OF THE FIGURES

FIG. 1 shows the basic semiconductor layers requiring the fabrication of a grating, according to one embodiment of the present invention.

FIG. 2 shows the semiconductor structure after the grating mask has been created, according to one embodiment of the present invention.

FIG. 3 shows the semiconductor structure after the in-situ etching of the grating pattern, according to one embodiment of the present invention.

FIG. 4 shows the semiconductor structure after the overgrowth session, according to one embodiment of the present invention.

FIG. 5 shows the semiconductor structure including the layers required to create the grating mask, according to one embodiment of the present invention.

FIG. 6 shows the semiconductor structure after the grating pattern has been defined in the photoresist, according to one embodiment of the present invention.

FIG. 7 shows the semiconductor structure after the non-selective etching process has been performed, according to one embodiment of the present invention.

FIG. 8 shows the semiconductor structure after the selective etching process has been performed, according to one embodiment of the present invention.

### DETAILED DESCRIPTION OF THE INVENTION

The present invention provides a method of manufacturing gratings in semiconductor materials. The method is suitable for a wide range of applications, and is particularly appropriate for fabricating gratings for distributed feedback lasers, gratings for distributed Bragg reflectors, and filters based on optical waveguides with grating structures. The invention provides an improved accuracy of the grating depth and shape, and a reduction in contaminants in the final semiconductor structure, with consequent improved performance and manufacturing repeatability.

The present invention is a combination of in-situ etching using a grating mask that is formed in semiconductor material only and the subsequent overgrowth of additional semiconductor material to enclose the grating structure prior to exposure to the atmosphere and the contaminants therein. The present invention is based on a two-stage process. First the grating pattern is defined in a semiconductor material, which is the grating mask. This grating mask is created at a position above the material that is to ultimately contain the grating pattern. Upon the completion of the fabrication of the grating mask, the semiconductor structure is moved to a reactor, where in the second stage, the grating pattern defined by the grating mask is transferred into the underlying semiconductor layers by in-situ etching. The grating is subsequently overgrown with additional semiconductor material while in the same reactor, thereby not exposing the etched grating pattern to the atmosphere thereby reducing the contaminants in the grating structure of the semiconductor laser.

The combination of the grating mask that is defined in semiconductor material and the in-situ etching and overgrowth steps allows for the formation of gratings in a semiconductor laser with minimal contamination of the grating interface. As such, there is no need to compensate for n-type doping that would typically result from contamination at the interface. In addition, the present invention has an added benefit of providing grating depth uniformity over a full wafer, and process repeatability, which can be appealing in a repeated manufacturing setting.

The invention is suitable for the manufacture of a wide range of grating structures, provided a grating mask formed using semiconductor material only, can be produced. Suitable grating structures include regularly spaced corrugations, such as those found in a conventional DFB laser, variable spaced corrugations, such as those found in devices containing a chirped grating, and more complicated groups of corrugations, such as those found in devices containing a distributed Bragg reflector.

In addition, the present invention is suitable for use with a variety of semiconductor materials, including In(Ga,As)P compounds such as InP, GaAs, InGaAs, and InGaAsP. The semiconductor materials could additionally include N, wherein such a material can be InGaNAs, for example. The semiconductor material can additionally include Sb, wherein such a material can be InGaAsNSb, for example. In addition, manufacturing of gain-coupled gratings in active regions comprising multiple quantum-well/quantum-barrier stacks which are formed in various In(Ga,As)P materials can be performed using the method according to the present invention.

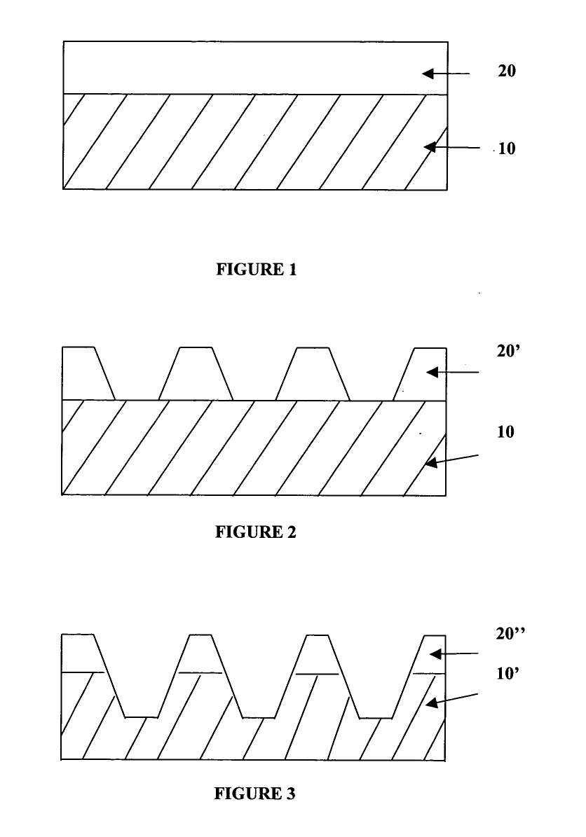

FIG. 1 shows a cross-sectional view of a semiconductor structure prior to the etching of a grating as defined in accordance with the present invention. Layer 10 is the material to receive the grating pattern and this layer may be comprised of multiple layers of semiconductor material. Where the grating is to be a gain-coupled grating, layer 10 will include the active region of the device, and therefore may additionally include a quantum well/quantum barrier stack therein. Where the grating is to be an index-coupled grating, layer 10 will include the material into which the grating is defined, typically a layer having a composition selected from the In(Ga,As)P material system on top of InP, for example. There may be additional layers in the structure beneath layer 10, not represented in this diagram. Layer 20 is the material into which the semiconductor grating mask is defined, wherein this layer may be comprised of multiple layers of semiconductor material. According to the present invention, the material used to form layer 20 is a semiconductor material that is suitable for the laser structure being fabricated.

The composition of layer 10 will depend on whether the grating is to be gain-coupled or index-coupled. According to one embodiment of the invention, the method is used to manufacture a gain-coupled grating, wherein layer 10 can comprise a series of quantum wells and quantum barriers comprising various InGaAsP compounds. The top of layer 10 can be either the first barrier in the quantum-well/quantum-barrier stack, or it can be a layer of InGaAsP comprising a portion of the separate confining heterojunction above the quantum-well/quantum-barrier stack.

According to another embodiment of the present invention, the method can be applied to an index-coupled grating, wherein layer 10 can comprise InGaAsP on top of InP. For both gain-coupled and index-coupled grating applications, in one embodiment the top of layer 10 comprises InGaAsP material with a composition such that its peak photoluminescence is at 1.10 μm wavelength or longer.

The structure represented in FIG. 1 is etched to produce the structure represented in FIG. 2. Layer 20 has been patterned to make a semiconductor grating mask, which is represented as layer 20′.

The structure represented in FIG. 2 is placed into an epitaxial reactor where in-situ etching is used to transfer the grating pattern into layer 10, thereby yielding patterned layer 10′ represented in FIG. 3. During the in-situ etching, the grating mask formed from semiconductor material, layer 20′, is etched, thereby producing layer 20″. In one embodiment of the invention, it is also possible that layer 20′ is completely etched away during the in-situ etching process.

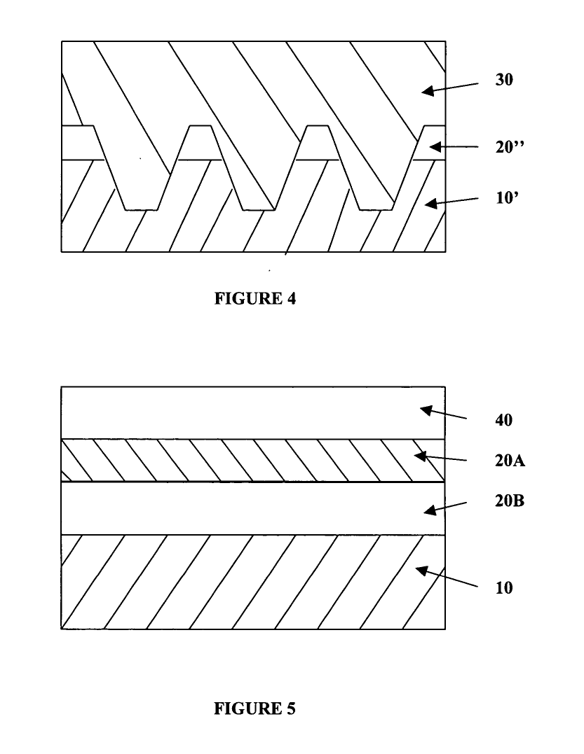

Without removing the present semiconductor structure from the reactor, additional semiconductor material from the In(Ga,As)P material system, which is labeled as layer 30 in FIG. 4, is grown on top of the patterned layers 10′ and 20″ thereby yielding the structure represented in FIG. 4. The finished grating structure for the semiconductor laser is defined by the corrugation in layers 10′ and 20″. Additional layers, not represented in FIG. 4, may be grown on top of layer 30 for example. When the structure is removed from the reactor the region with the grating pattern is sealed inside the semiconductor, and hence is protected from the deposition of contaminants. Between the etching and the overgrowth steps there is no opportunity for contamination of the grating structure interface since the environment within the reactor can be controlled, thereby yielding a reproducible manufacturing process with low levels of contamination at the grating structure interface.

In one embodiment of the invention, the material grown in layer 30 is the same composition as the material in layer 20″, and as such after the overgrowth session layers 30 and 20″ are essentially indistinguishable. In one embodiment of the invention, the in-situ etching and overgrowth is conducted in an MOCVD reactor. It will be obvious to a worker skilled in the art that the application of other epitaxial growth technologies is possible, including chemical-beam epitaxy (CBE), molecular-beam epitaxy (MBE) and liquid-phase epitaxy (LPE).

A key part of this manufacturing process is the control of the physical depth of the transfer of the pattern into layer 10, wherein the etch rate is dependent on the materials being etched, the etchant, the etchant flux and the temperature. In one embodiment of this invention, the transfer of the grating pattern from layer 20′ to layer 10 is accomplished with in-situ etching using methyl iodide at a temperature between 550° C. and 600° C. Below 550° C., the etch rate can be too small to be useful, and above 600° C. there can be a deterioration in the quality of the gratings during the initial heating of the reactor prior to the etching process. It would be obvious to a worker skilled in the art that other organo-iodine compounds would be equally suitable etchants, including, but not limited to, hydrogen iodide, diiodomethane, triiodomethane, carbon tetraiodide, iodoethane, n-propyl iodide and isopropyl iodide. In addition, other compounds of other halogens would be suitable, including, but not limited to, hydrogen chloride and methyl chloride. As such the determination of suitable etchants would require initial testing in order to determine etch rates and suitability of the etchant with respect to the material system being used to fabricate the semiconductor laser, for example.

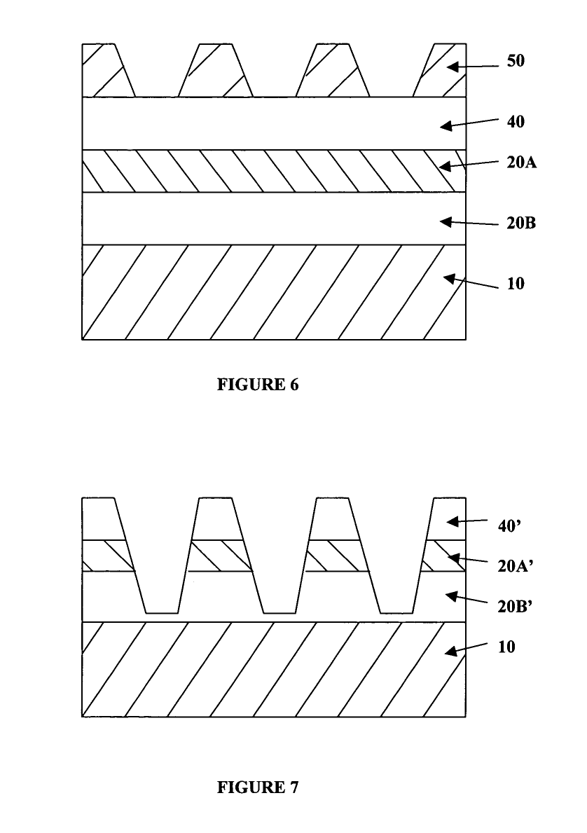

A further aspect of the invention is the means of forming the grating mask from semiconductor material, which is represented by layer 20′ in FIG. 2. To facilitate formation of the grating mask, layer 20′ is comprised of two materials, represented as layers 20A and 20B in FIG. 5, wherein an additional layer of material is grown on top of layer 20A, and is labeled 40. The three layers, 20A, 20B and 40 may be grown using any suitable epitaxial growth technique known in the art. For example, in addition to MOCVD, other techniques such as molecular beam epitaxy (MBE), chemical beam epitaxy (CBE) or liquid phase epitaxy (LPE) may be used to create these layers. Layer 20A is the etch-stop layer since it has properties suitable for an etch stop described below.

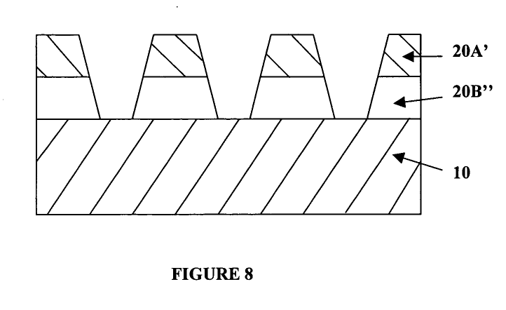

Conventional means are then used to create a grating pattern in a masking material on top of layer 40, which is represented by layer 50 in FIG. 6. The structure in FIG. 6 is then etched using a non-selective etchant that etches the materials in layers 40, 20A, and 20B, and subsequently the masking material 50 is removed, thereby yielding the structure shown in FIG. 7. The non-selective etching process is stopped when the grating has reached approximately the middle of layer 20B′. In the next step, the structure shown in FIG. 7 is etched using a selective etchant that etches the material in layers 40′and 20B′, but does not etch the material in layer 20A′ or the material in layer 10 and as such the material forming layer 20A′ is termed an etch-stop layer. The resulting structure after completion of this process is shown in FIG. 8.

The pattern in the semiconductor layers 20A′ and 20B″ illustrated in FIG. 8 is the semiconductor grating mask, which is depicted in FIG. 2 as layer 20′. During the in-situ etching and overgrowth described above, the layers 20A′ and 20B″ act as the mask pattern that is transferred into layer 10. In one embodiment, layer 20A′ is completely etched away during the in-situ etching such that layer 20″ in FIG. 3 is entirely comprised of material that was once layer 20B″.

In one embodiment of the invention, layers 20B and 40 comprise InP, and the etch-stop layer 20A is comprised of InGaAsP with an emission wavelength of 1.25 μm, and as mentioned previously, the top of layer 10 is comprised of InGaAsP with a 1.10 μm or longer emission wavelength. In one embodiment, the non-selective etchant used to transform the semiconductor structure between FIGS. 6 and 7 is aqueous iodic acid because this acid etches the InP (in layers 40 and 20B) and 1.25 μm InGaAsP (in layer 20A) at a controlled rate, thereby allowing the etch to be terminated approximately in the middle of layer 20B. In one embodiment, the selective etchant used to transform the semiconductor structure between FIGS. 7 and 8 is an aqueous solution of hydrochloric and phosphoric acids with proportions 10.8% HCl and 59.8% H₃PO₄ by weight. This embodiment of the selective etchant etches InP but does not etch InGaAsP with an emission wavelength 1.10 μm or longer. This selective etchant can remove InP from the bottom of the grating teeth until it reaches the 1.10 μm InGaAsP at the top of layer 10. The 1.25 μm emission wavelength InGaAsP in layer 20A′ preserves the grating pattern during this etch, thereby resulting in the semiconductor structure depicted in FIG. 8.

It will be obvious to those skilled in the art that the etch-stop layer 20A could also have a lower or higher value for its emission wavelength, such as 1.20 μm or 1.40 μm or any other wavelength achievable in the In(Ga,As)P material system as long as it resists etching by the selective etchant. In addition, the etch-stop layer may alternatively comprise a strained alloy and the etch-stop layer may also be any kind of material that is resistant to etching depending on the etchant being used in the patterning of layer 40. It will be obvious to workers skilled in the art that other embodiments of the invention may use different etch processes or etch chemistries, and that the choice of the etch process and chemistry would depend on the choice of composition of each semiconductor layer.

In one embodiment of the invention, the masking material in layer 50 is photoresist patterned holographically, a technique well known in the state of the art. Those skilled in the art will appreciate that any other suitable lithography process may be used to create the photoresist grating mask 50, including electron-beam lithography, near-field holography, and nano-imprint lithography. In addition a skilled worker will appreciate that the material in layer 50 may be a dielectric, such as SiO₂ or SiNₓ, and that the grating patterns may be created in such materials by conventional means. In addition, it would be readily apparent to a skilled worker that the grating pattern defined in layer 50 may be a uniform corrugation, or it may include phase jumps, chirped periods, or patches of gratings, and that in cases where the grating pattern is irregular, electron-beam lithography can be a favorable means of patterning the masking material, for example.

After the processing steps described in this invention are complete the semiconductor structure will be processed by conventional means to complete the device fabrication.

As illustrated in the Figures, the sizes of layers or regions are exaggerated for illustrative purposes and, thus, are provided to illustrate the general structures of the present invention. Various aspects of the present invention are described with reference to a layer or structure being formed on a substrate or other layer or structure. As will be appreciated by those of skill in the art, references to a layer being formed “on” another layer or substrate contemplates that additional layers may intervene.

In addition it would be readily understood by a worker skilled in the art that while the Figures illustrate a particular number of layers, each of these identified layers can be formed by a plurality of layers depending on the targeted application.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A method for manufacturing a grating pattern in one or more layers of semiconductor material, the method comprising the steps of:
(a) forming a grating pattern in a semiconductor material grown on top of the one or more layers, thereby forming a semiconductor grating mask;
(b) transferring the grating pattern into the one or more layers using in-situ etching in an epitaxial growth reactor; and
(c) overgrowing semiconductor material on the one or more layers prior to removal from the epitaxial growth reactor.

2. The method for manufacturing a grating pattern in one or more layers of semiconductor material according to claim 1, wherein the semiconductor material grown on top of the one or more layers includes an upper etch stop layer of semiconductor material and a lower layer of semiconductor material.

3. The method for manufacturing a grating pattern in one or more layers of semiconductor material according to claim 2, wherein the upper etch stop layer is completely etched away during the step of transferring the grating pattern.

4. The method for manufacturing a grating pattern in one or more layers of semiconductor material according to claim 2, wherein the step of forming a grating pattern comprises the steps of:
(a) creating a desired grating pattern in a masking material deposited on the semiconductor material grown on top of the one or more layers, thereby defining a mask;
(b) partially etching said semiconductor material grown on top of the one or more layers as defined by the mask;
(c) stripping the masking material; and
(d) selectively etching the semiconductor material grown on top of the one or more layers, said etch stop layer and said one or more layers terminating said step of selectively etching, thereby forming the semiconductor grating mask.

5. The method for manufacturing a grating pattern in one or more layers of semiconductor material according to claim 4, wherein the masking material is a photoresist patterned holographically,

6. The method for manufacturing a grating pattern in one or more layers of semiconductor material according to claim 4, wherein the masking material is a dielectric.

7. The method for manufacturing a grating pattern in one or more layers of semiconductor material according to claim 1, wherein the epitaxial growth reactor is a MOCVD reactor.

8. The method for manufacturing a grating pattern in one or more layers of semiconductor material according to claim 1, wherein the one or more layers of semiconductor material are selected from a In(Ga,As)P material system.

9. The method for manufacturing a grating pattern in one or more layers of semiconductor material according to claim 8, wherein the one or more layers of semiconductor material further comprise N.

10. The method for manufacturing a grating pattern in one or more layers of semiconductor material according to claim 8, wherein the one or more layers of semiconductor material further comprise Sb.

11. The method for manufacturing a grating pattern in one or more layers of semiconductor material according to claim 1, wherein the one or more layers include a layer of InGaAsP on top of InP.

12. The method for manufacturing a grating pattern in one or more layers of semiconductor material according to claim 1, wherein the one or more layers of semiconductor material include a top layer of InGaAsP material with a composition having a peak photoluminescence at 1.10 μm or longer.

13. The method for manufacturing a grating pattern in one or more layers of semiconductor material according to claim 1, wherein in-situ etching uses methyl iodide at a temperature between 550° C. and 600° C.

14. The method for manufacturing a grating pattern in one or more layers of semiconductor material according to claim 2, wherein the etch stop layer is InGaAsP with an emission wavelength of 1.25 μm.

15. The method for manufacturing a grating pattern in one or more layers of semiconductor material according to claim 4, wherein the lower layer of semiconductor material and the masking material comprise InP.

16. The method for manufacturing a grating pattern in one or more layers of semiconductor material according to claim 15, wherein the step of selectively etching uses an aqueous solution of HCl and H₃PO₄ with proportions 10.8% HCl and 59.8% H₃PO₄ as an etchant.

17. The method for manufacturing a grating pattern in one or more layers of semiconductor material according to claim 15, wherein the step of partially etching uses an aqueous iodic acid etchant.

18. The method for manufacturing a grating pattern in one or more layers of semiconductor material according to claim 1, wherein material grown during the step of overgrowing and material of the semiconductor grating mask have identical compositions.
